(19) United States
(12) Patent Application Publication
(10) Pub. No.: US 2026/0313759 A1
(43) Pub. Date: Oct. 8, 2026

(54) METHOD FOR OPERATING AN INDUCTION HEATING APPARATUS, AND IN-DUCTION HEATING APPARATUS

(71) Applicant: E.G.O. Elektro-Gerätebau GmbH, Oberderdingen (DE)

(72) Inventors: Wenlong Wang, Suzhou (CN); Ulrich Wächter, Bruchsal (DE); Marcus Frank, Sulzfeld (DE); Elmar Herweg, Oberderdingen (DE)

(21) Appl. No.: 19/571,963

(22) Filed: Mar. 19, 2026

(30) Foreign Application Priority Data
Apr. 2, 2025 (DE) 10 2025 112 957.6

(51) Int. Cl. H05B 6/06; H03K 17/081; H05B 6/04; H05B 6/12

(52) U.S. Cl. CPC H05B 6/062; H05B 6/04; H05B 6/1209; H03K 17/08116

(57) ABSTRACT

A method is provided for operating an induction heating apparatus (100) that includes a DC voltage intermediate circuit (1) having a positive intermediate circuit branch (1a) carrying a positive intermediate circuit potential and a negative intermediate circuit branch (1b) carrying a negative intermediate circuit potential, with an intermediate circuit DC voltage (9) present between the branches. The apparatus further includes a parallel resonant circuit with a capacitor (2) and an induction heating coil (3) connected in parallel with the capacitor, the coil being configured to generate a magnetic alternating field for heating cookware (200), as well as a semiconductor switching means (4). The parallel resonant circuit (2, 3) and the semiconductor switching means (4) are connected in series between the positive and negative intermediate circuit branches, and at the beginning of heating the method includes actuating the semiconductor switching means (4) using a first PWM signal at a first frequency during a charging period to charge the capacitor (2).

### CROSS-REFERENCE TO RELATED APPLICATIONS

This application claims priority to German Application No. 10 2025 112 957.6, filed Apr. 2, 2025, the contents of which are hereby incorporated herein in its entirety by reference.

The invention is based on the object of providing a method for operating an induction heating apparatus, and an induction heating apparatus, which allow operation of the induction heating apparatus in a manner that protects the components as much as possible.

The method according to the invention is used for operating an induction heating apparatus.

The induction heating apparatus has a DC voltage intermediate circuit with a positive intermediate circuit branch that carries a positive intermediate circuit potential, and a negative intermediate circuit branch that carries a negative intermediate circuit potential. During operation of the induction heating apparatus, an intermediate circuit DC voltage is present between the positive intermediate circuit branch and the negative intermediate circuit branch.

The induction heating apparatus also has a parallel resonant circuit having a capacitor and an induction heating coil connected in parallel with the capacitor, wherein a magnetic alternating field for heating an item of cookware is able to be generated by means of the induction heating coil.

The induction heating apparatus also has a semiconductor switching means, in particular precisely one semiconductor switching means, for example in the form of an IGBT.

The parallel resonant circuit and the semiconductor switching means are looped in in series between the positive intermediate circuit branch and the negative intermediate circuit branch.

The induction heating apparatus also has a control unit, for example in the form of a microprocessor controller, that actuates the semiconductor switching means in such a way that a method described below is carried out.

At the beginning or the start of heating, the method has the step of: actuating the semiconductor switching means by means of a first PWM signal at a first frequency during a charging period for (pre)charging the capacitor.

In one embodiment, the first frequency is in a frequency range of between 200 kHz and 3 MHz.

In one embodiment, the first PWM signal has a duty cycle of less than 20%.

In one embodiment, the charging period is in a range of between 0.5 μs and 5 μs. The charging period may alternatively also be selected in a variable manner in such a way that a voltage across the semiconductor switching means is less than a maximum voltage, for example becomes less than 150 V, in particular less than 100 V.

In one embodiment, following the beginning of heating or following the steps described above, the method has the subsequent further step of: actuating the semiconductor switching means by means of a second PWM signal at a second frequency.

In one embodiment, the second frequency is in a range of between 20 kHz and 65 kHz.

In one embodiment, the second PWM signal has a duty cycle in a range of between 15% and 25%.

In one embodiment, the induction heating apparatus has a DC voltage supply for generating the intermediate circuit DC voltage, in particular in a stabilized manner. The DC voltage supply is preferably designed to generate the intermediate circuit DC voltage in a stabilized manner in such a way that the intermediate circuit DC voltage is generated independently of any load within a predetermined voltage range, for example in a voltage range of between 200 V and 240 V.

The invention is described in detail below with reference to the drawings. In the drawings:

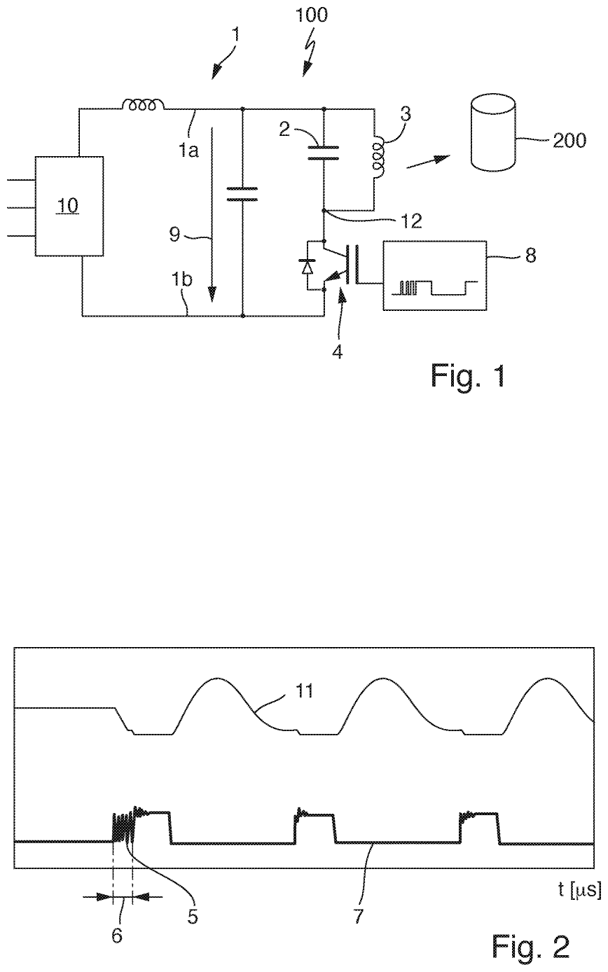

FIG. 1 shows a schematic circuit diagram of an induction heating apparatus, and

FIG. 2 shows signals over time of the induction heating apparatus shown in FIG. 1.

FIG. 1 shows a schematic circuit diagram of an induction heating apparatus 100.

The induction heating apparatus 100 has a DC voltage intermediate circuit 1 with a positive intermediate circuit branch 1a that carries a positive intermediate circuit potential, and a negative intermediate circuit branch 1b that carries a negative intermediate circuit potential. An intermediate circuit DC voltage 9 is present between the positive intermediate circuit branch 1a and the negative intermediate circuit branch 1b.

The induction heating apparatus 100 also has a parallel resonant circuit having a capacitor 2 and an induction heating coil 3 connected in parallel with the capacitor 2, wherein a magnetic alternating field for heating an item of cookware 200 is able to be generated by means of the induction heating coil 3.

The induction heating apparatus 100 also has a semiconductor switching means 4 in the form of an IGBT, wherein the parallel resonant circuit 2, 3 and the semiconductor switching means 4 are looped in in series between the positive intermediate circuit branch 1a and the negative intermediate circuit branch 1b.

The induction heating apparatus 100 also has a control unit 8 that actuates the semiconductor switching means 4 in such a way that a method described below is carried out.

The induction heating apparatus 100 also has a DC voltage supply 10 for generating the intermediate circuit DC voltage 9 in a stabilized manner.

FIG. 2 shows a voltage 11 at the collector 12 of the semiconductor switching means 4, a first PWM signal 5 and a second PWM signal 7 following the first PWM signal 5 over time, wherein the PWM signals 5 and 7 are generated by means of the control unit 8 and are used to actuate the semiconductor switching means 4.

As shown, the semiconductor switching means 4 is actuated by means of the first PWM signal 5 at a first frequency during a charging period 6 for charging the capacitor 2. The first frequency is in a range of between 200 kHz and 3 MHz. The first PWM signal 5 has a duty cycle of less than 20%. The charging period 6 is in a range of between 0.5 μs and 5 μs.

Following the beginning of heating or following the end of the charging period 6, the semiconductor switching means 4 is actuated by means of the second PWM signal 7 at a second frequency. The second frequency is in a range of between 20 kHz and 65 kHz. The second PWM signal 7 has, in a manner dependent on the heating power, a duty cycle in a range of between 15% and 60%.

The present invention provides a method for actuating a gate connection of an IGBT in connection with quasi-resonant switching of an induction heating apparatus, which is supplied with power from a stabilized DC voltage supply.

The intermediate circuit voltage has a high level while there is no heating taking place, which, in conventional solutions, results in a high collector current when the IGBT is switched on.

When the intermediate circuit is presently being fed from a stabilized DC voltage supply, the intermediate circuit is not able to be discharged, since, unlike when the intermediate circuit is being supplied with power by a mains rectifier, there is no zero crossing of the AC voltage supply system feeding the mains rectifier.

According to the invention, at the start of the heating, the resonant circuit capacitor is charged by means of a high-frequency pulse pattern, which protects the semiconductor switching means or the IGBT against damage.

By way of example, a plurality of pulses are used to actuate the IGBT in order to reduce the collector current upon startup. By way of example, the actuation frequency may be 1.55 MHz with a duty cycle of 17%.

After, for example, 4 pulses, the frequency may be changed to the normal operating frequency of, for example, 40 kHz with a duty cycle of 20%.

According to the invention, the maximum collector current that occurs may be significantly reduced to protect the IGBT against damage. The method according to the invention does not require any change to the conventional actuation topology.

1. A method for operating an induction heating apparatus (100),
wherein the induction heating apparatus (100) has:
a DC voltage intermediate circuit (1) with a positive intermediate circuit branch (1a) that carries a positive intermediate circuit potential, and a negative intermediate circuit branch (1b) that carries a negative intermediate circuit potential, wherein an intermediate circuit DC voltage (9) is present between the positive intermediate circuit branch (1a) and the negative intermediate circuit branch (1b),
a parallel resonant circuit having a capacitor (2) and an induction heating coil (3) connected in parallel with the capacitor (2), wherein a magnetic alternating field for heating an item of cookware (200) is able to be generated by means of the induction heating coil (3), and
a semiconductor switching means (4),
wherein the parallel resonant circuit (2, 3) and the semiconductor switching means (4) are looped in in series between the positive intermediate circuit branch (1a) and the negative intermediate circuit branch (1b),
wherein, at the beginning of heating, the method has the step of:
actuating the semiconductor switching means (4) by means of a first PWM signal (5) at a first frequency during a charging period (6) for charging the capacitor (2).

2. The method as claimed in claim 1, wherein
the first frequency is in a range of between 200 kHz and 3 MHz.

3. The method as claimed in claim 1, wherein
the first PWM signal (5) has a duty cycle of less than 20%.

4. The method as claimed in claim 1, wherein
the charging period (6) is in a range of between 0.5 μs and 5 μs.

5. The method as claimed in claim 1, wherein,
following the beginning of heating, the method has the step of:
actuating the semiconductor switching means (4) by means of a second PWM signal (7) at a second frequency.

6. The method as claimed in claim 5, wherein
the second frequency is in a range of between 20 kHz and 65 kHz.

7. The method as claimed in claim 5, wherein
the second PWM signal (7) has a duty cycle in a range of between 15% and 60%.

8. An induction heating apparatus (100), having:
a DC voltage intermediate circuit (1) with a positive intermediate circuit branch (1a) that carries a positive intermediate circuit potential, and a negative intermediate circuit branch (1b) that carries a negative intermediate circuit potential, wherein an intermediate circuit DC voltage (9) is present between the positive intermediate circuit branch (1a) and the negative intermediate circuit branch (1b),
a parallel resonant circuit having a capacitor (2) and an induction heating coil (3) connected in parallel with the capacitor (2), wherein a magnetic alternating field for heating an item of cookware (200) is able to be generated by means of the induction heating coil (3),
a semiconductor switching means (4),
wherein the parallel resonant circuit (2, 3) and the semiconductor switching means (4) are looped in in series between the positive intermediate circuit branch (1a) and the negative intermediate circuit branch (1b), and
a control unit (8) that actuates the semiconductor switching means (4) in such a way that a method as claimed in one of the preceding claims is carried out.

9. The induction heating apparatus (100) as claimed in claim 8, having:
a DC voltage supply (10) for generating the intermediate circuit DC voltage (9), in particular in a stabilized manner.
